(19) United States
(12) Patent Application Publication
(10) Pub. No.: US 2009/0016857 A1
(43) Pub. Date: Jan. 15, 2009

(54) SUBSTRATE-REPLACING APPARATUS, SUBSTRATE-PROCESSING APPARATUS, AND SUBSTRATE-INSPECTING APPARATUS

(75) Inventor: Yuzo NAKAMURA, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Olympus Corporation, Tokyo (JP)

(21) Appl. No.: 12/183,318

(22) Filed: Jul. 31, 2008

Related U.S. Application Data
(63) Continuation of application No. PCT/JP2007/051693, filed on Feb. 1, 2007.

(30) Foreign Application Priority Data
Feb. 1, 2006 (JP) P2006-025095

(51) Int. Cl. H01L 21/67

(52) U.S. Cl. 414/222.01

(57) ABSTRACT

A substrate-replacing apparatus that passes a first substrate received from a first carrying part to a second carrying part, and passes a second substrate received from said second carrying part to said first carrying part, including said second carrying part that can move forward and backward along a direction orthogonal to a lamination direction of said first substrate and said second substrate, a supporting member that can move relatively in the lamination direction of said substrates with respect to said second carrying part, a first holding part that is attached to said supporting member, and can hold one of said first substrate and said second substrate, and a second holding part that is attached to said supporting member at a predetermined distance from the first holding member in the lamination direction of said substrates, and can hold another one of said first substrate and the second substrate; said supporting member and said second carrying part being moved relatively such that, when one of said first holding part and said second holding part is used in receiving said first substrate from said first carrying part, another one of the first substrate and said second substrate is used in receiving said second substrate from said first carrying part.

This application is a continuation application based on a PCT Patent Application No. PCT/JP2007/051693, filed Feb. 1, 2007, whose priority is claimed on Japanese Patent Application No. 2006-025095, filed Feb. 1, 2006. The contents of both the PCT Application and the Japanese Application are incorporated herein by reference.

### TECHNICAL FIELD

The present invention relates to a substrate-replacing apparatus used for delivering a substrate to a processing apparatus and the like, a substrate-processing apparatus that includes a substrate-replacing apparatus and performs predetermined processes to a substrate, and a substrate-inspecting apparatus that includes a substrate-replacing apparatus and inspects a substrate.

### BACKGROUND ART

An example of a conventional replacing apparatus is one that includes two carrier arms, and sequentially supplies two or more masks to an exposure device (e.g. see Patent Document 1). A first carrier arm suction-holds a first mask, carries it into the exposure device, and mounts it at a predetermined position. After the first mask has been used, the first carrier arm carries it to its original position. Meanwhile, a second carrier arm carries a second mask into the exposure device, and mounts it at a predetermined position. Thus the first and second carrier arms alternately carry masks into and out from the exposure device.

Another example is an apparatus which includes a buffer stage, and which replaces a processed substrate on a processing apparatus with an unprocessed substrate (e.g. see Patent Document 2). This apparatus operates consecutively positioning substrates such as semiconductors, and, in the case that the apparatus handles two substrates, when a first substrate is carried in by a robot arm, it positions the first substrate and lifts it before making it wait. A second substrate subsequently carried in by the robot arm is positioned, and made to wait below the first substrate. When carrying out the substrate, the first substrate and the second substrate are carried out sequentially.

[Patent Document 1] JPA No. 62-195143

[Patent Document 2] US Patent 2003/053904

### DISCLOSURE OF THE INVENTION

### Problems to be Solved by the Invention

However, since a configuration such as that disclosed in Patent Document 1 includes two moving parts, the apparatus is complex to configure and requires a large installation space. Furthermore, in a configuration such as that disclosed in Patent Document 2, an open/close driving part and the like are provided such that, when the buffer stage, after positioning the first substrate, lifts the first substrate and makes it wait, a passing arm part of the buffer stage opens and closes in order to avoid interfering with the hook part of the buffer stage. Since conventional configurations include many driving parts for realizing the buffer function in this manner, the apparatus is complex to configure.

This invention has been realized in view of the above problems, and mainly aims to realize a buffer function with a simple configuration and without requiring a large space.

### Means for Solving the Problems

To solve the above objects, the invention provides a substrate-replacing apparatus that passes a first substrate received from a first carrying part to a second carrying part, and passes a second substrate received from said second carrying part to said first carrying part: the apparatus comprising said second carrying part that can move forward and backward along a direction orthogonal to a lamination direction of said first substrate and said second substrate; a supporting member that can move relatively in the lamination direction of said substrates with respect to said second carrying part; a first holding part that is attached to said supporting member, and can hold one of said first substrate and said second substrate; and a second holding part that is attached to said supporting member at a predetermined distance from said first holding member in the lamination direction of said substrates, and can hold another one of said first substrate and said second substrate; and wherein said supporting member and said second carrying part being moved relatively such that, when one of said first holding part and said second holding part is used in receiving said first substrate from said first crying part, another one of said first holding part and second holding part is used in receiving said second substrate from said first carrying part.

This substrate-replacing apparatus uses different holding parts when passing a substrate to a carrying part that carries one substrate, and when receiving a substrate from the carrying part. For example, when a substrate being held by the first holding part is passed to the carrying part, if the carrying part runs holding another substrate or a processed substrate, the second holding part receives this substrate. Meanwhile, a substrate carried into the first holding part by another means is passed to the empty carrying part. Depending on the arrangement of the carrying part, the functions of the first and second holding parts can be reversed.

### EFFECTS OF THE INVENTION

According to the invention, when replacing a substrate carried by a carrying part, a holding part that passes the substrate to the carrying part is a different one from a holding part that receives the substrate from the carrying part, thereby enabling the substrate carried by the carrying part to be replaced efficiently. Therefore, the apparatus can be configured more simply than when two carrying parts carry one substrate. Also, since there is no need to provide spaces and a mechanism for separately moving two carrying parts, the apparatus can be made smaller.

### BRIEF DESCRIPTION OF THE DRAWINGS

FIG. 1 A plan view of the configuration of a substrate-replacing apparatus according to an embodiment of the invention.

FIG. 2A A perspective view along arrow A of FIG. 1.

FIG. 2B An enlarged view of the vicinity of a first mount part of FIG. 1.

FIG. 3 An explanatory view of a step of carrying a substrate into a substrate-replacing apparatus.

FIG. 4 A view of a state where a substrate is passed from a first mount part to a mounting stage.

FIG. 5 A view of a processed substrate being returned to a substrate-replacing apparatus while an unprocessed substrate is waiting on a first mount part.

FIG. 6 A view of lifting a lifting stage, and receiving a substrate from a mounting stage at a second mount part.

FIG. 7 A partially enlarged plan view of another aspect of a substrate-replacing apparatus.

FIG. 8 A perspective view along arrow B of FIG. 7.

FIG. 9 A side view of a substrate-inspecting apparatus.

### REFERENCE NUMERALS

1, 101 Substrate-replacing apparatus
4 Moving stage (carrying part, first carrying part, second carrying part)
5 Prealignment mechanism (aligner)
7 Mounting stage (carrying part, first carrying part, rotating stage)
12 Lifting mechanism (moving mechanism)
21, 22, 23, 24 Supporting members
31, 32, 33, 34 First mount parts (first holding parts)
41, 42 Centering references
51, 52, 53, 54 Second mount parts (second holding part)
60 Alignment mechanism (aligner)
70 Processing apparatus
80 Robot arm (second carrying part, first carrying part)
111 Two-axis stage (moving mechanism)
W Substrate
Z Lamination direction

### BEST MODE FOR CARRYING OUT THE INVENTION

Preferred embodiments of the invention will be explained with reference to the drawings. The invention is not, however, limited to the following embodiments, and constituent elements of these embodiments can, for example, be combined as appropriate.

### First Embodiment

A substrate-replacing apparatus according to a first embodiment of the invention will be explained in detail with reference to the drawings.

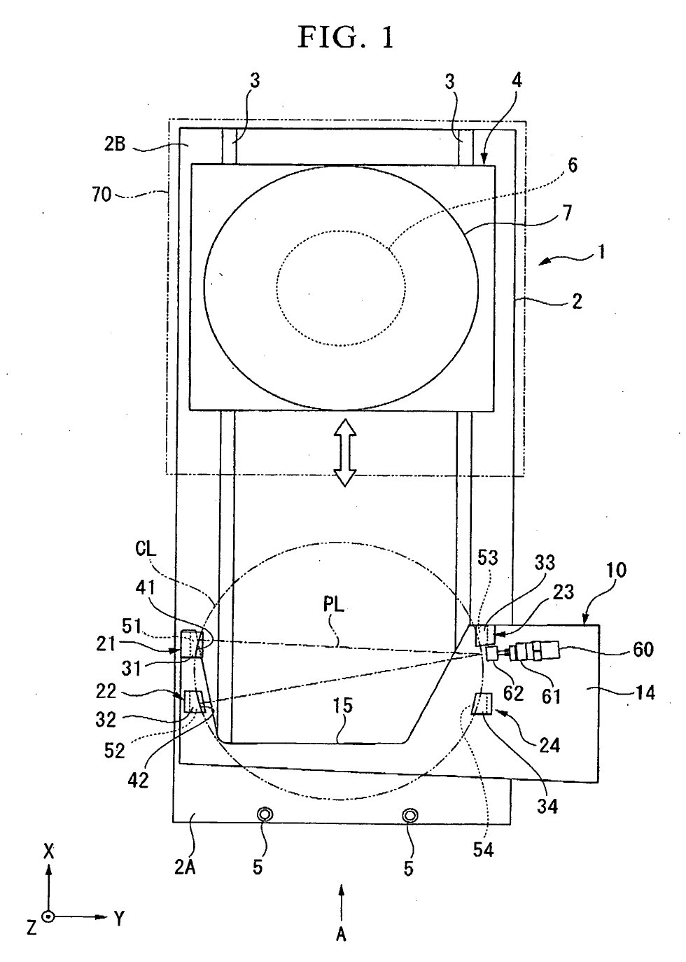

As shown in FIG. 1, a substrate-replacing apparatus 1 includes an elongated mount 2. A pair of rails 3 are arranged on the mount 2, parallel to its long direction (X direction). As a carrying unit, a moving stage 4 is attached to these rails 3. By means of a moving mechanism (not shown), the moving stage 4 can move on the rails between one end 2A of the mount 2 and another end 2B. As an aligner, a prealignment mechanism 5 is provided at the one end 2A side of the mount 2. Each prealignment mechanism 5 is provided one by one at an equal position from the center in the Y direction (direction orthogonal to the rails 3) of a mounting stage 7, and optically detects the position of the substrate. A circular-headed pole 6 is provided on the moving stage 4 (first and second carrying parts), and the mounting stage 7 is provided at a top end of the pole 6 such that the substrate can be mounted on it. The mounting stage 7 has a larger diameter than the pole 6. A plurality of sucking parts (not shown) for suction-holding the substrate are arranged on a top face of the mounting stage 7. As these sucking parts, it is possible to use a suction type such that the outer peripheral edge of the circular shape of the mounting stage 7 is one step higher, and a plurality of pins have same height as the outer peripheral edge are arranged on the inner side of the circle, and air is sucked from a space formed by the substrate, the outer peripheral edge, and the bottom face where the pins are arranged, or a suction type such as concentric or radial grooves are arranged on the mounting stage 7, and air is sucked from a space of the grooves, as a type known as a total-face suction stage that sucks air. Tubes and the like for pulling the mounting stage 7 by suction are provided on the inner side of the pole 6.

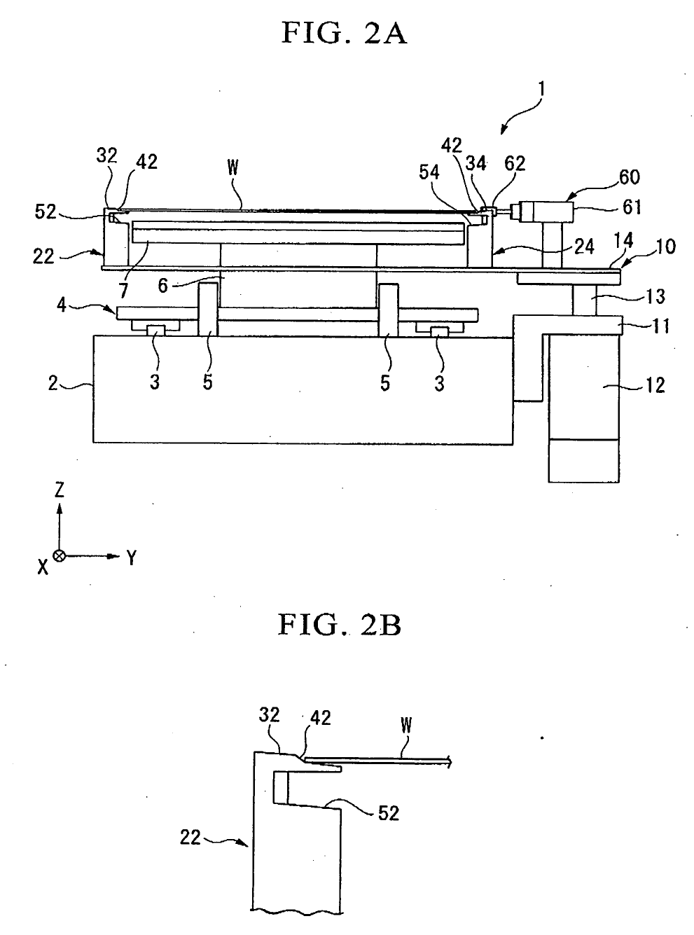

A substrate-replacing unit 10 is provided at the end 2A side of the mount 2. As shown in FIG. 2, the substrate-replacing unit 10 includes a lifting mechanism 12 (moving mechanism) that is attached to the side of the mount 2 by a bracket 11. The lifting mechanism 12 includes a pole screw, a linear guide, and a motor. A linear motor can also be used. The lifting mechanism 12 moves a rod 13 (see FIG. 2) forward and backward in a vertical direction (Z direction), and an end of a lifting stage 14 is secured to a tip of the rod 13. The lifting stage 14 is arranged above the moving stage 4 and below the mounting stage 7.

As shown in FIG. 1, a notch 15 is provided in the lifting stage 14 to enable it to receive the pole 6 of the moving stage 4. Supporting members 21, 22, 23, and 24 are arranged in pairs near two opposite sides of the lifting stage 14 with the notch 15 therebetween. The supporting members 21 to 24 are arranged along the circumference of an imaginary circle CL corresponding to the outer peripheral face of the substrate.

Top end faces of the supporting members 21 to 24 constitute first mount parts 31, 32, 33, and 34 (first holding parts) which support the outer edge of the substrate from below. The first mount parts 31 to 34 are constituted by mount faces which tilt at a predetermined angle toward the center of the imaginary circle CL. As aligners, centering references 41 and 42 are formed by steps made at an angle rising vertically above the first mount parts 31 to 34, which are shaped such as to match the external shape of the substrate, i.e. the circular arc of the imaginary circle CL, and are provided respectively in the first mount parts 31 and 32. That is, the centering references 41 and 42 match the position of the outer face of the substrate when it is arranged correctly. As shown in FIGS. 2A and 2B, the centering references 41 and 42 are inclined with respect to the Z axis, minimizing the contact area with the outer peripheral face of a substrate W in the lifting direction. The incline direction of the centering references 41 and 42 is such as to separate from the outer peripheral face of the substrate as the substrate rises when it is lifted from the first mount parts 31 and 32.

Second mount parts 51, 52, 53, and 54 (second holding parts) are attached to the supporting members 21 to 24, a predetermined length below the first mount parts 31 to 34 in the Z direction. The second mount parts 51 to 54 are mount faces formed by notching the supporting members 21 to 24, and support the outer edge of the substrate W from below. The second mount parts 51 to 54 incline at a predetermined angle toward the center of the imaginary circle CL in the same manner as the first mount parts 31 to 34.

As shown in FIG. 1, a centering apparatus 60 is provided as a aligner between the supporting members 23 and 24. The centering apparatus 60 is held at approximately the same height as the first mount parts 33 and 34, and includes a pusher 61 which moves the rod to and from the centering references 41 and 42 as shown by an imaginary line PL, and a pressing member 62 which is provided at the tip of the pusher 61. The pressing member 62 is manufactured from a softer material than the substrate W. The pressing force of the pusher 61 is set such that it does not damage the substrate W.

The other end 2B side of the mount 2 forms one part of a processing apparatus 70. The XY direction is the direction parallel to the movement of the substrate W. The up-down Z direction is the face direction of the substrate W, i.e. the direction when the substrate W is laminated.

Subsequently, effects of this embodiment will be explained. This explanation describes an example where two substrates W are supplied sequentially to the processing apparatus 70. To distinguish the two substrates W, the first is termed substrate W1, and the second, substrate W2.

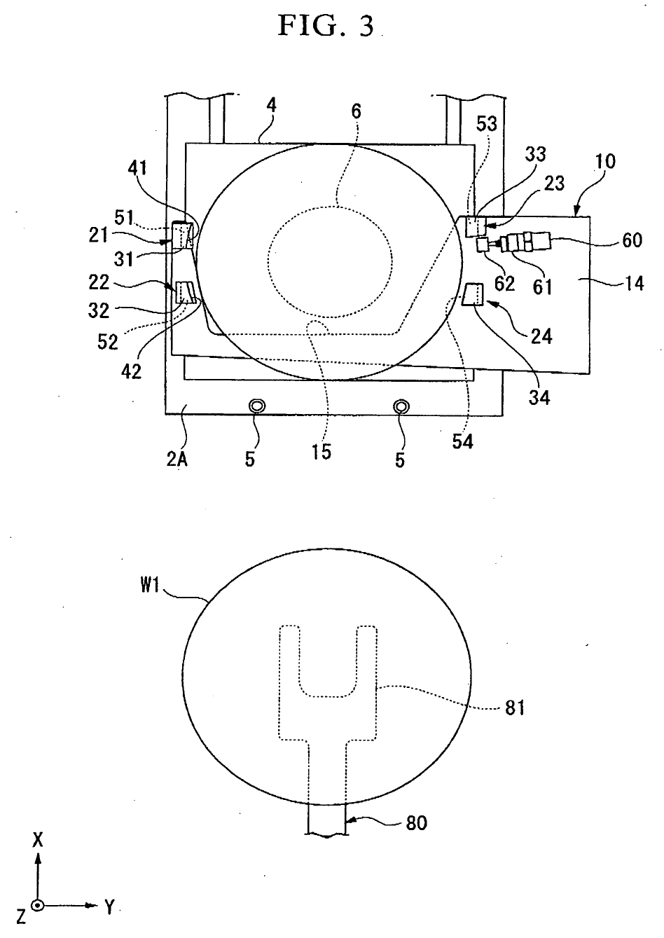

As shown in FIG. 3, in an initial state, the moving stage 4 is waiting at the end 2A side. The pole 6 of the moving stage 4 is inside the notch 15 of the lifting stage 14. The lifting mechanism 12 makes the lifting stage 14 wait such that the mounting stage 7 is below the first mount parts 31 to 34, and above the second mount parts 51 to 54. Since the supporting members 21 to 24 are arranged further to the outside than the outer periphery of the mounting stage 7, irrespective of their positions in the Z direction, there is no interference between the supporting members 21 to 24 (mount parts 31 to 34, and 51 to 54) and the mounting stage 7.

The substrates W1 and W2 are carried from another step in a state of being stowed in a substrate cassette (not shown). A robot arm 80 (second or first carrying part) uses a cry arm 81 at its tip to extract the fit substrate W from the substrate cassette, and carry it into the substrate-replacing apparatus 1 from one end 2A of the mount 2. At this time, the prealignment mechanism 5 arranged on the mount 2 detects the edge of the substrate W1. A detection result is input to a controller of the robot arm 80, and the position of the carrying arm 81 is corrected such that the center of the substrate W1 in the Y direction matches the center of the mounting stage 7. The prealignment mechanism 5 includes sensors that detect reflection-type or transmission-type changes in the quantity of light; when the substrate W mounted on the carrying arm 81 is moved at a constant speed in the X direction, based on the time until there is a change in the quantity of light at two sensors on the left and right, and the time difference between them, the prealignment mechanism 5 detects the amount of deviation in the central position of the substrate W from the reference position of the carrying arm 81. In this embodiment, the prealignment mechanism 5 is provided to the substrate-replacing apparatus 1, however it can be provided on the mounting stage side of the substrate cassette, where it can detect the amount of deviation of the substrate W from the reference position when the substrate W is carried from the substrate cassette.

The robot arm 80 inserts the substrate W1 above the first mount parts 31 to 34 while correcting the position of the substrate W1, and then cancels the suction of the carrying arm 81. If the substrate W1 rises onto the first mount parts 31 and 32 due to problems of prealignment precision, and if problems are caused by interference and the like, the robot arm 80 corrects the position of the substrate W1 to the plus side of the Y direction (the centering apparatus 60 side of the reference position). The substrate-replacing apparatus 1 makes a controller apparatus (not shown) lift the lifting stage 14. When the positions of the first mount parts 31 to 34 become higher than the height of the first substrate W1, the first mount parts 31 to 34 lift the outer edge of the substrate W1 by supporting it from below. Since the height of the carrying arm 81 does not change, the substrate W1 that was supported by the carrying arm 81 is mounted onto (received by) the four first mount parts 31 to 34 (see FIG. 2). Since each of the first mount parts 31 to 34 is inclined, the substrate W1 is supported near its center. The robot arm 80, which delivered the substrate W1 and is not holding a subsequent substrate, is retracted, and exited from the substrate-replacing apparatus 1. The centering apparatus 60 is then operated such that its pressing member 62 presses the outer peripheral face of the substrate W1, pushing the outer peripheral face of the opposite side against the centering references 41 and 42. The position of the substrate W1 is thus mechanically aligned. As a result, the center of the imaginary circle CL, the center of the substrate W1, and the center of the mounting stage 7 are accurately coincided.

The portions of the centering references 41 and 42 are formed from sliding members that can slide in the Y directions. When no substrate is mounted, the sliding members at the reference position are arranged at the outer side with respect to the center position of the substrate, and, when the first mount part receives a substrate, the sliding members at the reference position can move to the reference position in conjunction with the movement of the centering apparatus 60, centering it by clasping it from both sides. This makes it possible to prevent problems such as the substrate rising onto the first mount parts 32 and 32 due to insufficient prealignment precision, even if the position of the robot arm is not corrected to the plus sides of the Y direction.

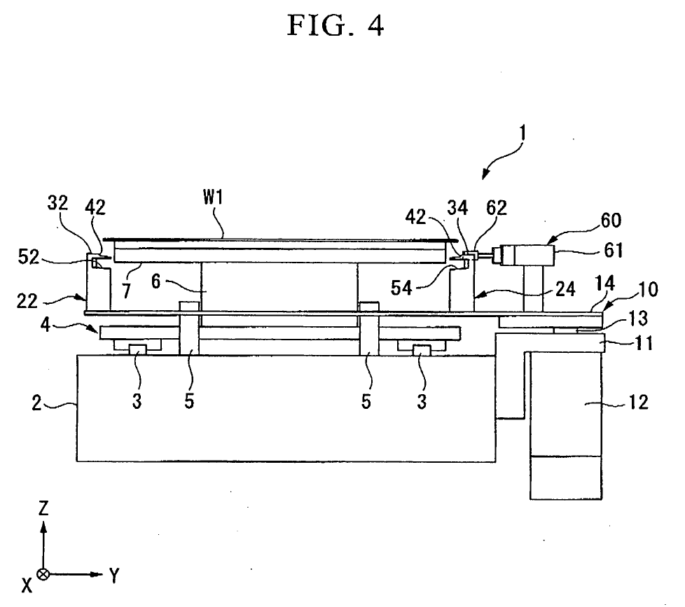

When the substrate W1 is mounted on the first mount parts 31 to 34, the lifting mechanism 12 is lowered. Since the first mount parts 31 to 34 only support the substrate W1 from below, when their height sinks lower than the mounting stage 7, as shown in FIG. 4, the inner peripheral part of the substrate W1 is supported by the mounting stage 7, while the outer peripheral part of the substrate W1 instead separates from the first mount parts 31 to 34.

The substrate W1 is prealigned by the first mount parts 31 to 34. Therefore, the mounting stage 7 holds the substrate W1 by suction. In this way, when the substrate W1 moves from the first mount parts 31 to 34 to the mounting stage 7 (when the mounting stage 7 receives the substrate W1), the operation of the lifting mechanism 12 is stopped. The moving stage 4 is then moved to the other end 2B side of the mount 2, and the processing apparatus 70 performs predetermined processes to the substrate W1. Examples of these processes are receiving the substrate W1 from the mounting stage 7, using a spin coater to coat it with a resist, and using an exposure device for patterning it.

Since the substrate-replacing unit 10 becomes empty after the substrate W1 is passed from the first mount parts 31 to 34 to the mounting stage 7, while the processing apparatus 70 is performing the processes, the robot arm 80 extracts the second substrate W2 from the substrate cassette and carries it into the substrate-replacing apparatus 1. The substrate W2 is positioned and mounted by the first mount parts 31 to 34 in the same manner as the substrate W1 described above.

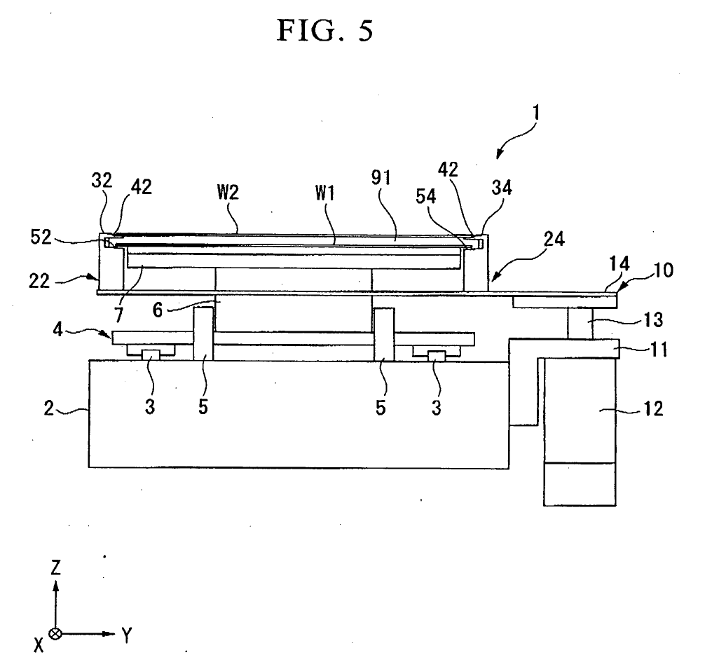

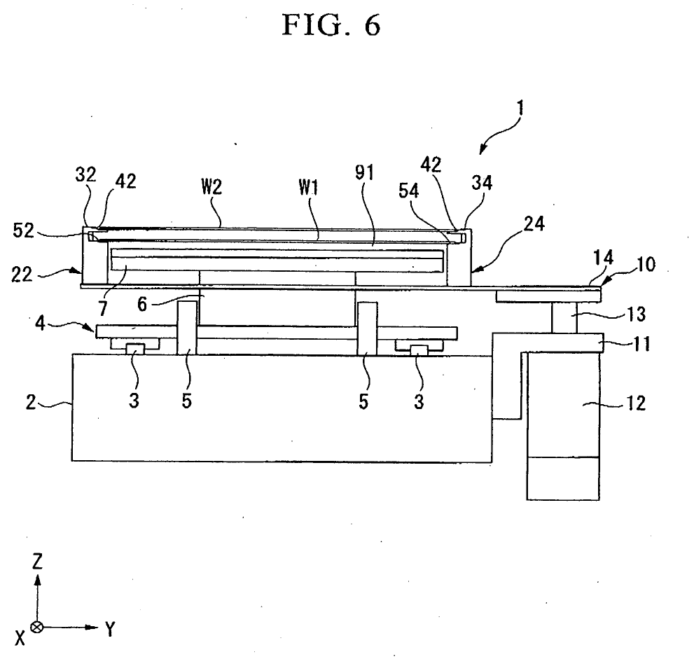

After processing at the processing apparatus 70 ends, the first substrate W1 is returned onto the mounting stage 7. The moving stage 4 carries the substrate W1 to a position on the end 2A side of the mount 2 where the center of the substrate W1 matches the center of the imaginary circle CL. As shown in FIG. 5, the substrate-replacing unit 10 waits such that the first substrate W1 is carried in slightly above the second mount parts 51 to 54, and below the first mount parts 31 to 34, i.e. below the second substrate W2. After the suction of the mounting stage 7 is cancelled, the lifting mechanism 12 lifts the lifting stage 14. When the height of the second mount parts 51 to 54 exceeds that of the mounting stage 7, the outer edge of the first processed substrate W1 is supported from below by the second mount parts 51 to 54. As a result, as shown in FIG. 6, the substrate W1 is moved (passed) from the top face of the mounting stage 7 to the second mount parts 51 to 54.

Since a gap 91 is provided under the processed substrate W1, the robot arm 80 inserts the carrying arm 81 (see FIG. 3) into this gap 91. The robot arm 80 then receives the first substrate W1 by scooping it up from below with the carrying arm 81, and holds it by suction. The substrate W1 is thus moved (passed) from the second mount parts 51 to 54 to the robot arm 80. At this time, the movement of robot arm 80 is controlled such that the first substrate W1 does not contact the second substrate W2 mounted on the first mount parts 31 to 34. After receiving the first substrate W1, the robot arm 80 moves back, and inserts the first substrate W1 into a cassette for storing processed substrates.

When the first substrate W1 strays from the operating range of the substrate-replacing apparatus 1, the lifting mechanism 12 lowers the lifting stage 14. The second substrate W2 mounted on the first mount parts 31 to 34 is moved (passed) to the mounting stage 7 in the same manner as described above. Thereafter, while the substrate W2 is being processed in the processing apparatus, an unprocessed substrate is mounted on the first mount parts 31 to 34; when a processed substrate returns, it is carried out after processing by the second mount parts 51 to 54, and the unprocessed substrate that was waiting on the first mount parts 31 to 34 is passed to the mounting stage 7.

In this embodiment, in carrying substrates W on the moving stage 4 that moves forward and backward, since the substrate-replacing unit 10 replaces the processed substrate W1 with the unprocessed substrate W2, a substrate W to be processed can made to wait until a processed substrate returns. Therefore, a great many substrates W can be passed to the processing apparatus 70 in a short time. There is needless to provide a plurality of moving stages 4, and there is just one driving mechanism which need not be complex, whereby the cost and size of the apparatus can be reduced. Moreover, since the substrate W can be aligned while it is waiting on the first mount parts 31 to 34, the tact time can be further shortened. Since the prealignment mechanism 5 makes a rough alignment, the substrate W can be easily positioned by the centering apparatus 61 and the centering references 41 and 42. Also, since the first mount parts 31 to 34 and 51 to 54 include faces that incline toward the center of the substrate W, the position of the substrate W is unlikely to deviate during the steps of passing it and receiving it.

When the moving stage 4 is used as a first carrying part and the robot arm 80 is used as a second carrying part, similar effects can be obtained with respect to the robot arm 80. The first mount parts 31 to 34 are used receiving the substrate W from the robot arm 80, and another substrate W is passed from the second mount parts 51 to 54 to the robot arm 80, enabling a great many substrates W to be passed to the robot arm 80 in a short period of time. Since there is needless to provide a plurality of robot arms 80 and no need for a complex mechanism, the cost and size of the apparatus can be reduced.

### Second Embodiment

A second embodiment of the invention will be explained with reference to the drawings. In this embodiment, the configuration of a substrate-replacing unit differs from that of the first embodiment. Therefore, the same reference numerals are denoted to the same constituent elements, and there is no repetitious explanation.

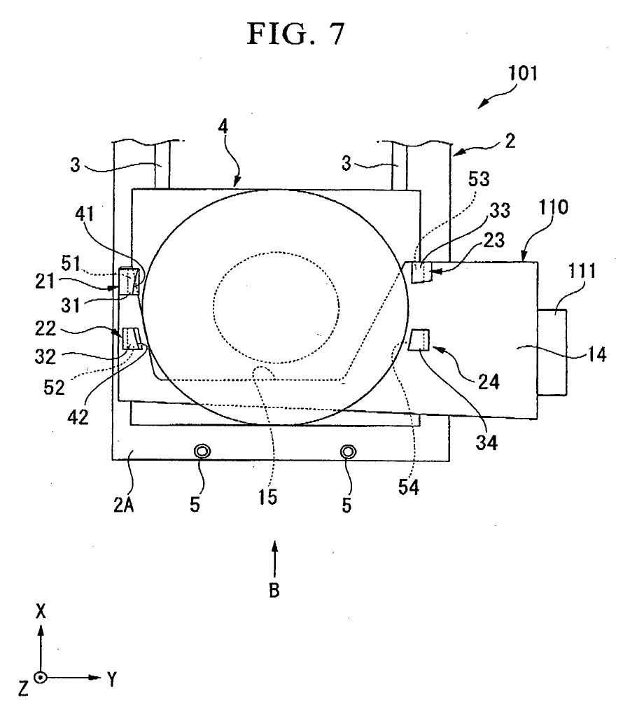

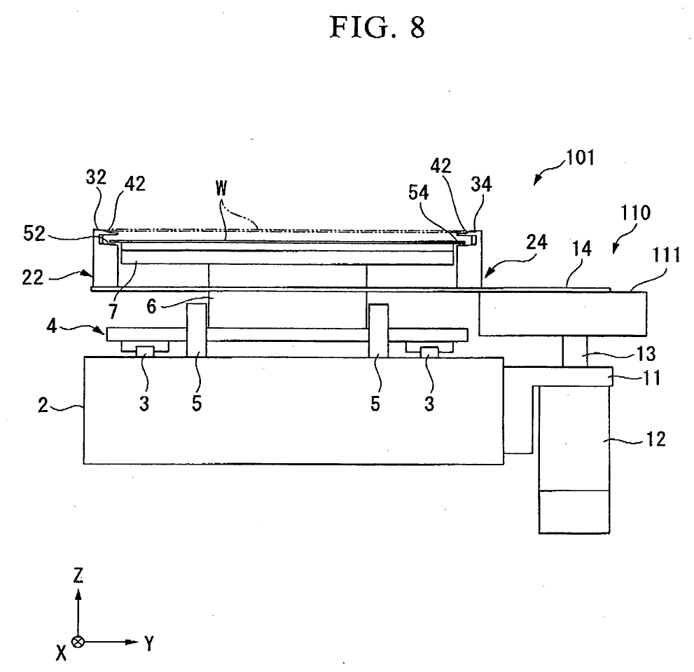

As shown in FIGS. 7 and 8, a substrate-replacing apparatus 101 includes a substrate-replacing unit 110. This substrate-replacing unit 110 includes a two-axis stage 111 (moving mechanism), which is provided at a tip of a rod 13 of a lifting mechanism 12, and can freely moves in two directions, the X direction and the Y direction. On the other hand, it does not include a centering apparatus and centering references, as in the first embodiment.

Effects of the substrate-replacing apparatus 101 will be explained. When a first substrate W1 is received from a robot arm 80, a prealignment mechanism 5 detects the position of the substrate W1, and, if the position of the substrate W1 deviates from the center of the mounting stage 7, a control device (not shown) computes a deviation amount. When the substrate W1 is mounted onto the first mount parts 31 to 34, the two-axis stage 111 is moved such as to correct this deviation amount. Therefore, since the position of the substrate W1 is aligned such that its center matches the center of the mounting stage 7, in that position, the lifting stage 14 is lowered and the substrate W1 is passed from the first mount parts 31 to 34 to the mounting stage 7. Processing thereafter is similar to that of the first embodiment.

According to this embodiment, since the two-axis stage 111 can moved the substrate W parallel to the X and Y directions, the substrate W can be aligned by a noncontact procedure. Other effects are similar to those of the first embodiment. Means for detecting the deviation amount of the substrate W is not limited to a prealignment mechanism, it being possible to use a conventional position-detecting means.

The invention is not limited to the embodiments described above, and can be widely applied.

For example, while the substrate-replacing apparatuses 10 and 110 of this embodiment move freely in the Z direction, they can instead be secured in the Z direction, while allowing the moving stage 4 which is the carrying part, and the robot arm 80, to move in the Z direction. The configuration can also be one where the lifting stage 14 can move in the X direction. Even if the moving stage 4 is fixed, the substrate W can be replaced. Similar effects and advantages can be achieved in this case.

Also, the moving stage 4 can support the pole 6 such that it can rotate, while using a motor (not shown) to rotate the pole 6 around the Z-axis. Since the mounting stage 7 becomes a rotating stage, a substrate W that is carried into the processing apparatus 70 can be coated with a resist and such like in that state. A notch-detecting sensor can be provided on the lifting stage 14. The notch-detecting sensor is provided at a position corresponding to a peripheral part of the substrate W, and detects change in the quantity of light when the rotating stage is rotated. The substrate W can be detected based on the large change in the quantity of light in its notched part. As the notch-detecting sensor can be used a transmission type or a reflection type. A line sensor, and a two-dimensional image-pickup device also be used. This notch-detecting sensor can also be used as a sensor for alignment. Furthermore, by adding a mechanism that enables the substrate W to be held at an inclination is added, it can be used in a visual appearance inspection apparatus.

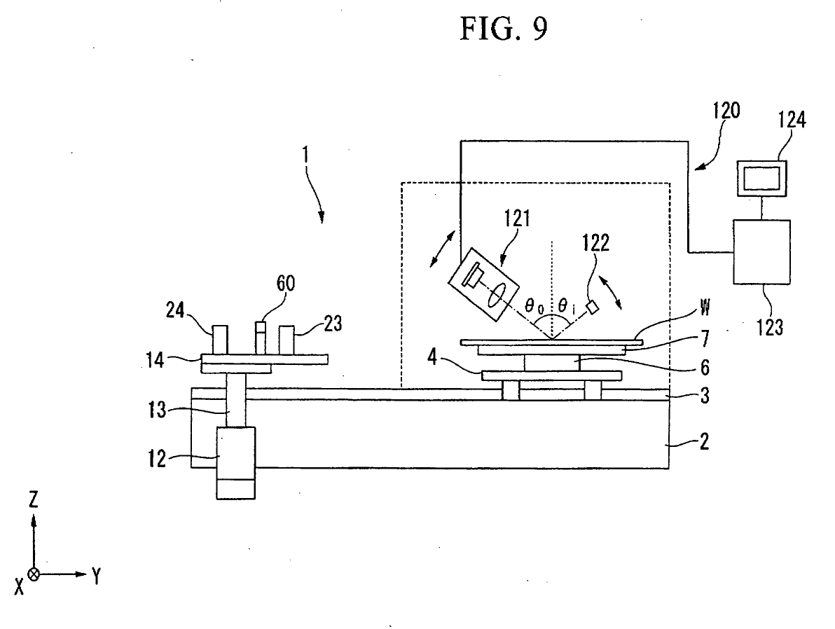

Moreover, as shown in FIG. 9, the substrate-replacing apparatuses 1 and 101 can be provided with an image pickup apparatus 121 and an illuminating apparatus 122 as an inspection unit 120, thereby structuring a substrate-inspecting apparatus. The image pickup apparatus 121 can be comprised of a two-dimensional image pickup device (a CCD etc.), or a line sensor. When using a line sensor, if line illumination is used for the illuminating apparatus 122, it becomes possible to capture an image of the entire face of the substrate W while moving the moving stage 4 in the Y direction. A signal from the image pickup apparatus is sent to an image processing apparatus 123, which detects faults using conventional image processing. A monitor 124 displays a detection result. Furthermore, the irradiation angle θᵢ and the imaging angle θ₀ of the image pickup apparatus 121 and the illuminating apparatus 122 can be altered using a rotating mechanism (not shown). Highly precisely positioning is possible using an alignment mechanism. If the mounting stage 7 is configured as a rotating stage, and the configuration is one that allows notch detection as mentioned above, the rotation angle of the substrate W can also be positioned precisely. Accordingly, the substrate-replacing apparatuses 1 and 101 can be used as appropriately a substrate-inspecting apparatus.

It is acceptable if the substrate-replacing apparatuses 1 and 101 include only the substrate-replacing units 10 and 110. In this case, if a robot arm is used instead of the moving stage 4, the substrate can be replaced via interaction between two robot arms. The robot arms can be used for storing substrates sequentially, or for carrying substrates to and from another processing apparatus.

Moreover, the substrate-replacing apparatuses 1 and 101 can include a second carrying unit, such as the robot arm 80. They can also be configured as part of the processing apparatus 70.

The substrate W can be one of various types, such as a semiconductor wafer, a glass wafer, and a large substrate for liquid crystal. A target other than the substrate W is also acceptable.

The first and second mount parts, 31 to 34, 51 to 54 can hold the inner peripheral side of the substrate W, whereas the mounting stage 7 and the robot arm 80 hold the outer peripheral side of the substrate W.

The lamination direction of the substrate W is not limited to up and down. For example, when carrying the substrate W in an approximately upright state, the first holding parts and second holding parts are arranged in the X and Y direction at a predetermined distance. In this case, the configuration allows the holding parts to suction-hold the outer edge of the substrate.

1. A substrate-replacing apparatus that passes a first substrate received from a first carrying part to a second carrying part, and passes a second substrate received from said second carrying part to said first carrying part, comprising:
said second carrying part that can move forward and backward along a direction orthogonal to a lamination direction of said first substrate and said second substrate;
a supporting member that can move relatively in the lamination direction of said substrates with respect to said second carrying part;
a first holding part that is attached to said supporting member, and can hold one of said first substrate and said second substrate; and
a second holding part that is attached to said supporting member at a predetermined distance from said first holding member in the lamination direction of said substrates, and can hold another one of said first substrate and said second substrate; wherein
said supporting member and said second carrying part being moved relatively such that, when one of said first holding part and said second holding part is used in receiving said first substrate from said first carrying part, another one of said first substrate and said second substrate is used in receiving said second substrate from said first carrying part.

2. The substrate-replacing apparatus according to claim 1, comprising a moving mechanism that moves said supporting member in the lamination direction of said substrate, wherein said first substrate and said second substrate being moved to said two carrying parts by moving said supporting member in the lamination direction of said substrate.

3. The substrate-replacing apparatus according to claim 2, wherein said supporting member can move such that, at said first carrying part, one of said first substrate and said second substrate is received into said first holding part, and another of said first substrate and said second substrate is passed from said second holding part, and, at said second carrying part, a substrate is received into said second holding part, and a substrate is passed from said first holding part.

4. The substrate-replacing apparatus according to claim 1, wherein said second carrying part comprises a rotating stage that rotates said first substrate and said second substrate.

5. The substrate-replacing apparatus according to claim 1, wherein said first carrying part comprises a robot arm that carries said first substrate out from a cassette for storing said first substrate, mounts it on said first holding part, and carries said second substrate in which a predetermined process thereto having been completed, from said second holding part into a cassette.

6. The substrate-replacing apparatus according to claim 2, a mount face, which holds said first substrate and said second substrate at said first holding part and said second holding part, tilts toward centers of said substrates.

7. The substrate-replacing apparatus according to claim 1, comprising a moving mechanism that moves said supporting member in the lamination direction of said substrate, wherein said moving mechanism being capable of moving in two axis directions that are orthogonal to the up-down direction of said supporting member.

8. The substrate-replacing apparatus according to claim 1, comprising an aligner that aligns the position of said first substrate and said second substrate held by said first holding part.

9. The substrate-replacing apparatus according to claim 1, wherein said first holding part and said second holding part are arranged such that they do not interfere with those of said two carrying parts within their range of relative movement.

10. A substrate-processing apparatus comprising the substrate-replacing apparatus according to claim 1.

11. A substrate-inspecting apparatus comprising the substrate-replacing apparatus according to claim 1.
